(19) United States
(12) Patent Application Publication
(10) Pub. No.: US 2016/0066415 A1
(43) Pub. Date: Mar. 3, 2016

(54) MULTILAYER WIRING BOARD

(71) Applicants: DENSO CORPORATION, Kariya-city (JP); MEISEI GAKUEN, Tokyo (JP)

(72) Inventors: Ryohei KATAOKA, Okazaki-shi (JP); Kouji KONDOH, Toyohashi-shi (JP); Jyun AKIMICHI, Aichi-ken (JP); Kanji OTSUKA, Tokyo (JP); Yutaka AKIYAMA, Tokyo (JP); Kaoru HASHIMOTO, Yamato-shi (JP)

(21) Appl. No.: 14/834,483

(22) Filed: Aug. 25, 2015

(30) Foreign Application Priority Data
Aug. 28, 2014 (JP) 2014-174167

(51) Int. Cl. H05K 1/02; H05K 1/11; H05K 7/02

(52) U.S. Cl. CPC H05K 1/0245; H05K 7/02; H05K 1/0298; H05K 1/11; H05K 2201/10719

(57) ABSTRACT

A multilayer wiring board includes an insulating layers stacked on one another, lands formed on an upper surface part of the multilayer wiring board, and a differential transmission line formed on or in each of the insulating layer. An electronic component is mounted on the lands. The differential transmission line is constituted of a pair of signal lines which extend from the lands toward a signal receiving end. Each of the signal lines is provided with an open stub which extends in a stacking direction of the insulating layers, and has a same width as a width of the signal lines, one end of the open stub being connected to a corresponding one of the signal lines, and another end of the open stub being open.

This application claims priority to Japanese Patent Application No. 2014-174167 filed on Aug. 28, 2014, the entire contents of which are hereby incorporated by reference.

### BACKGROUND OF THE INVENTION

1. Field of the Invention

The present invention relates to a multilayer wiring board.

2. Description of Related Art

A multilayer wiring board used for information devices with a CPU includes a stack of insulating layers. Each of the insulating layers is formed with a wiring pattern on its upper or lower surface. The wiring patterns of the adjacent insulating layers are electrically connected through vias. For example, refer to Japanese Patent Application Laid-open No. 2008-235338. In such a multilayer wiring board, data transmission between semiconductor chips, for example, between a CPU and a memory or between a CPU and a device connected to the CPU is performed through the wiring patterns.

Recently, the operation speed and data transmission rate of LSIs are increasing rapidly. For example, the signal transmission rate of an enterprise server used for big data processing and a motherboard of an enterprise router is specified to be 28 Gbps (14 GHz in clock frequency).

Meanwhile, it is known that a high frequency signal in the GHz band being transmitted on a signal line (wiring pattern) attenuates exponentially with the increase of its frequency. The attenuation characteristic in the S-parameter S21 of a signal line of a certain length is as shown by the solid line in FIG. 9. Generally, the limit transmission frequency fl of a signal below which the so-called eye pattern is open so that a receiver can take the signal without difficulty is −7 dB. When a desired signal transmission frequency is f2, it is necessary to enhance the attenuation characteristic as shown by the dotted line in FIG. 9 by elaborating the circuit structure of the receiver or a driver, or the signal line, to perform equalization. In a case where the equalization is performed using a circuit within a semiconductor chip (“active equalization” hereinafter), the operation speed of this circuit has to be very high, and the structure of the circuit becomes complicated.

The equalization may be performed by adding some component to the signal line of the board (“passive equalization” hereinafter). In the passive equalization, one of or both of a capacitor and an inductor is added at a position immediately after the driver or immediately before the receiver, or an LCR circuit constituted of an inductor, a capacitor and a resistor is provided, for example.

Such a passive equalization is effective for cases where the clock frequency is in a 5 GHz band. For cases of high frequency signals of 10 Gbps to 30 Gbps, the S21 parameter is greatly deteriorated even by a minute structural change in the electrodes or solder joints, for example. Accordingly, adding an LCR circuit may cause an adverse effect.

### SUMMARY

An exemplary embodiment provides a multilayer wiring board including:

insulating layers stacked on one another;

lands formed on an upper surface part of the multilayer wiring board, an electronic component being mounted on the lands; and

a differential transmission line formed on or in each of the insulating layers, the differential transmission line being constituted of a pair of signal lines which extend from the lands toward a signal receiving end, wherein

each of the signal lines is provided with an open stub which extends in a stacking direction of the insulating layers and has the same width as the width of the signal lines, one end of the open stub being connected to a corresponding one of the signal lines, and another end of the open stub being open.

Another exemplary embodiment provides a multilayer wiring board including:

insulating layers stacked on one another;

lands formed on an upper surface part of the multilayer wiring board, an electronic component being mounted on the lands; and

a differential transmission line formed on or in each of the insulating layers except the uppermost insulating layer, the differential transmission line being constituted of a pair of signal lines which extend from the lands toward a signal receiving end, wherein

each of the signal lines is provided with a stub which extends along a surface of the insulating layer and spreads in a width direction of the signal line.

According to each of the exemplary embodiments, there is provided a multilayer wiring board which makes it possible to transmit signals of high frequency with less attenuation in spite of its simple structure.

Other advantages and features of the invention will become apparent from the following description including the drawings and claims.

### BRIEF DESCRIPTION OF THE DRAWINGS

In the accompanying drawings:

FIG. 1 is a longitudinal cross-sectional view of a part of a multilayer wiring board according to a first embodiment of the invention;

FIG. 2 is a plan view of a differential transmission line section provided in the multilayer wiring board;

FIGS. 3A to 3E are longitudinal cross-sectional views of a part of the multilayer wiring board in manufacturing process;

FIG. 4 is diagrams showing a pulse signal waveform and a signal voltage waveform on a temporal axis in each of an ideal state (a) and a practical state (b);

FIG. 5 is diagrams showing the pulse signal waveform and a signal voltage waveform on a temporal axis in each of the practical state (a) and in a pre-emphasis state;

FIG. 6 is a longitudinal cross-sectional view of a part of a multilayer wiring board according to a second embodiment of the invention;

FIG. 7 is a plan view of a differential transmission line section provided in a multilayer wiring board according to a third embodiment of the invention;

FIG. 8 is a plan view of a differential transmission line section provided in a multilayer wiring board according to a fourth embodiment of the invention; and

FIG. 9 is a diagram showing a relationship between a clock frequency and attenuation of a signal transmitting on a signal line.

### PREFERRED EMBODIMENTS OF THE INVENTION

### First Embodiment

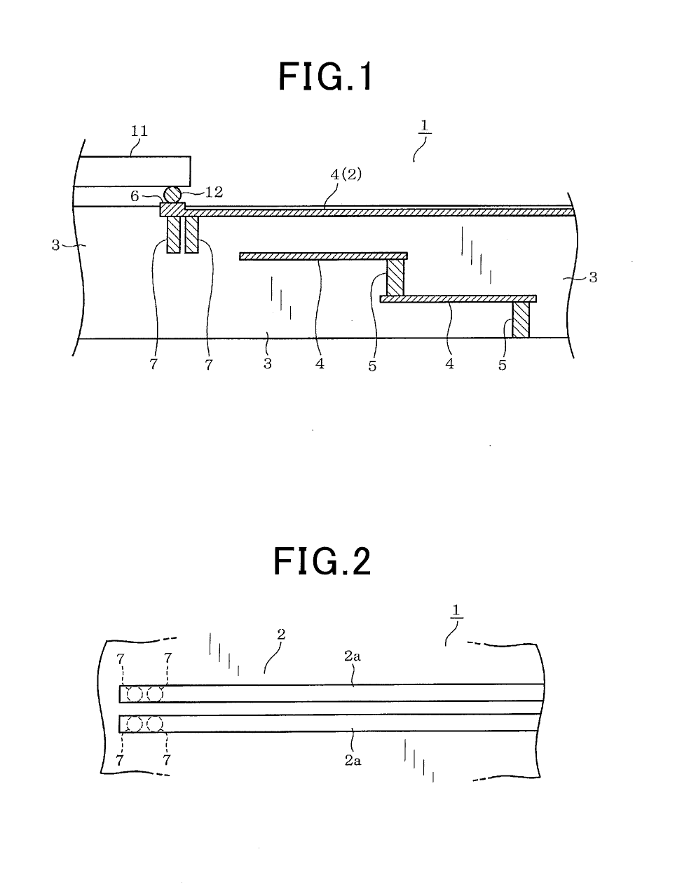

A multilayer wiring board 1 according to a first embodiment of the invention is described with reference to FIGS. 1 to 5. FIG. 1 is a longitudinal cross-sectional view schematically showing a part of the multilayer wiring board 1. FIG. 2 is a plan view of a differential transmission line 2 provided in the multilayer wiring board 1. The differential transmission line 2 is used for performing signal transmission at a high speed of 10 Gbps to 30 Gbps, for example.

As shown in FIG. 1, the multilayer wiring board 1 includes insulating layers 3 stacked on one another, each insulating layer 3 being made of thermoplastic resin material, for example. The surface of each of the insulating layers 3 is formed with a surface conductor pattern 4 made of copper foil, for example.

As described later, the surface conductor pattern 4 includes the differential transmission line 2. The multilayer wiring board 1 is provided with interlayer connecting sections (vias) 5 which vertically connect the surface conductor patterns 4 of the vertically adjacent insulating layers 3. In FIG. 1, the insulating layers 3 are three in number. However, actually, the number of the insulating layers 3 stacked on one another is from more than ten to several tens.

On the surface part (upper surface part) of the multilayer wiring board 1, there are formed many lands 6 on which electronic components 11 such as a CPU is mounted. The electronic component 11 is a BGA (Ball Grid Array) component, for example. The BGA component has the structure in which the mounting surface (the lower surface) of its rectangular package is provided with many ball-shaped solder bumps 12 arranged in a grid pattern. The electronic component 11 is mounted on the multilayer wiring board 1 by soldering the solder bumps 12 onto the lands 6.

As shown in FIG. 2, the differential transmission line 2 is constituted of a pair of signal lines 2a formed on the surface part of the multilayer wiring board 1. The signal lines 2a of the differential transmission line 2 are connected to the lands 6 at their proximal ends (signal transmitting ends) located on the left side in FIG. 2. The lands 6 are connected to output terminals of the electronic component 11. The signal lines 2a of the differential transmission line 2 extend parallel to each other to the right side in FIG. 2, and are connected at their distal ends (signal receiving ends) to another electronic component (an optical communication transponder, for example).

As shown in FIGS. 1 and 2, each of the signal lines 2a is provided with two open stubs 7 which are connected to the signal line 2a at one ends (upper ends) thereof and opened at the other ends (lower ends) thereof. The open stubs 7 are located in the vicinity of the lands 6 constituting the signal transmitting end of the signal lines 2a and arranged in twos in the direction in which the signal lines 2a extend. Each of the open stubs 7 is formed in a columnar shape having approximately the same width as the signal line 2a and extending in the stacking direction of the insulating layers 3 (depth direction).

Preferably, each open stub 7 is located within a distance smaller than 1% of the entire length of the differential transmission line 2 from the lands 6 serving as the signal transmitting end. Each open stub 7 may be formed immediately below the corresponding land 6. In this embodiment, the entire length of the differential transmission line 2 is 300 mm, the width of the signal lines 2a (or the diameter of the open stubs 7) is 100 μm, and the length in the depth direction of the open stubs 7 is 200 μm.

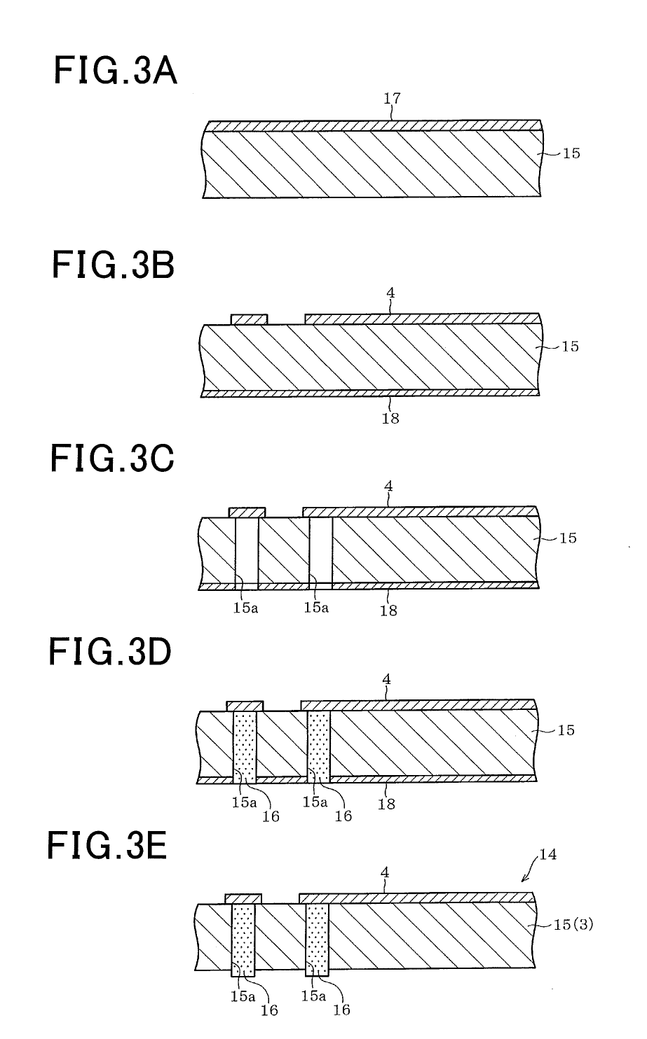

Next, a method of manufacturing the multilayer wiring board 1 having the above described structure is described with reference to FIG. 3. First, a substrate forming process is performed to form a substrate 14. As shown in FIG. 3E, the substrate 14 has a structure in which a sheet (film) 15 made of a thermoplastic resin of the crystal transition type constituting each insulating layer 3 is formed with the surface conductor pattern 4 (including the lands 6), and a conductive paste 16 is filled in via holes (see FIG. 3C) formed in places of the sheet 15. The conductive paste 16 filled in each via holes 15a forms the interlayer connecting section 5 and the open stub 7.

The sheet 15 is made of the material (product name “PAL-CLAD”) containing 35 to 65 wt % of polyether ether ketone (PEEK) resin, and 35 to 65 wt % of polyether imide (PEI) resin. The sheet 15 is formed in a rectangular shape corresponding to the shape of the multilayer wiring board 1 and having a thickness of 50 μm to 100 μm. This resin material is soft in a temperature range around 200° C., hard at temperatures higher or lower than this temperature range, and melts at temperatures above 400° C. This resin material remains hard even around 200° C. if its temperature falls from a higher temperature.

The substrate forming process begins in a step shown in FIG. 3A. In this step, a copper foil (of a thickness of 18 μm in this embodiment) 17 applied to the upper surface of the sheet 15 is etched to form the surface conductor pattern 4 including the lands 6. Next, a protection film 18 made of polyethylenenaphthalate (PEN), for example, is applied to the back surface of the sheet 15 as shown in FIG. 3B.

Next, a step shown in FIG. 3C is performed to form the via holes 15a bottomed by the surface conductor pattern 4 by irradiating a laser from the side having the protection film 18 or by drilling, for example. The via holes 15a are formed in places of the sheet 15 where the interlayer connecting section 5 and the open stub 7 should be formed. In this embodiment, the via holes 15a are formed using a carbon dioxide laser. The output power and the laser application time are adjusted so as not to make a hole in the surface conductor pattern 4. The via holes 15a corresponding to the open stubs 7 are formed so as to have the diameter which is approximately the same as the width of the signal line 2a of the differential transmission line 2.

Next, a step shown in FIG. 3D is performed to fill the via holes 15a with the conductive paste 16. The conductive paste 16 is made by mixing metal particles of silver and tin together with binder resin and organic solvent. In this embodiment, the conductive paste 16 is filled in the via holes 15a by screen printing using metal masks. Thereafter, the protection film 18 is peeled off from the sheet 15 to complete the substrate 14 as shown in FIG. 3E.

After completion of the substrate 14 as a base of each insulating layer 3 of the multilayer wiring board 1, a stacking process is performed to stack a plurality of the substrates 14. In this process, in a case where the length (depth) of the open stub 7 to be formed is larger than the thickness of one insulating layer 3, the via holes 15a are formed so as to penetrate through a plurality of the insulating layers 3 (a plurality of the substrates 14), and each via hole 15a is filled with the conductive paste 16. Although not shown in the drawings, a cover layer made of polyethylenenaphthalate (PEN), for example, is disposed on the upper surface of the upper-most substrate 14.

Next, a hot pressing process of hot-pressing the stacked product is performed. In this hot pressing process, the stacked product is set in a vacuum pressing machine to be pressed vertically at a pressure of 0.1 to 10 Mpa while being heated to a temperature of 200-350° C. In this process, since the sheets 15 of the respective substrates 14 are pressed in a softened state, they are fused to one another, and thereafter they crystallize (harden) to become united. Also at this time, the conductive pastes 16 within the via holes 15a harden to form the interlayer connecting sections 5 and the open stubs 7. After completion of the hot pressing process, the cover layer is removed.

Thereafter, a resist film is formed on a necessary part (excluding the lands 6) of the surface part of the multilayer wiring board 1, although not shown in the drawings. By these processes, there is completed the multilayer wiring board 1 provided with the surface conductor pattern 4 including the lands 6 and the differential transmission line 2 at the surface part of each insulating layer 3, and provided with the interlayer connecting sections 5 and the open stubs 7 thereinside. Thereafter, there is performed a reflow process for mounting the electronic components 11 such as a high-performance CPU, an optical communication transponder and a mass memory on the surface part of the multilayer wiring board 1.

In the multilayer wiring board 1 having the above described structure, a transmission signal outputted from the electronic component 11 is sent from the lands 6 to a receiving side through the pair of the signal lines 2a of the differential transmission line 2. The opens stubs 7 provided in the signal lines 2a serve as capacitors. Accordingly, since the timing at which the waveform of the transmission signal rises is delayed by the time necessary to charge the open stubs 7, a pre-emphasis waveform is obtained to thereby improve the attenuation characteristic.

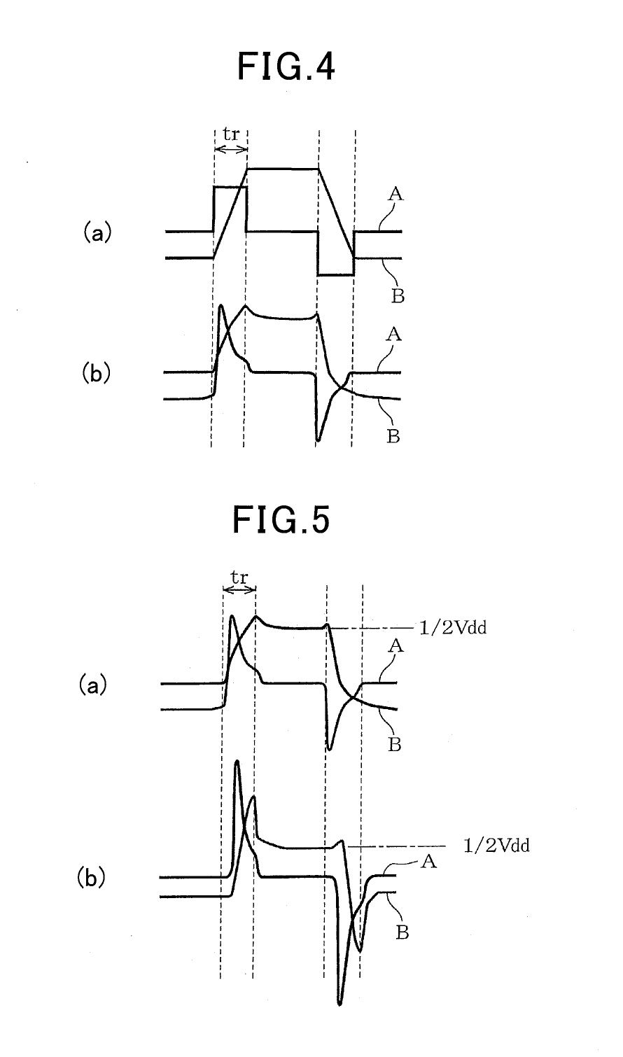

In the following, the function of the open stubs 7 are explained. Here, a capacitance C necessary for a passive equalizer at the 28 Gbps level is calculated. To this end, the effect of electric charge charged in the capacitor disposed immediately after a driver, which affects the rise time and a current of a pulse signal is considered (see FIG. 4 which shows a typical current waveform A and a typical signal voltage waveform B on a temporal axis in each of an ideal state (a) and a practical state (b) depending on the transistor characteristics and the power supply state).

For a case of an open end IO system, the voltage of the transmission signal is ½Vdd. When Vdd is 1 V and the signal amplitude voltage is 0.5 V, a relationship of Ron=Z0 is satisfied. Since Z0=100Ω, the current i is given by the equation of i=Vdd/(Ron+Z0)=5 mA when the signal rises.

When the signal falls, a current flows in the opposite direction to discharge the capacitor. In the following, the function of the open stubs 7 is explained mainly for a rising period of the pulse signal (transmission signal). In the ideal state, during the rising period tr, a current i flows as shown by the line A in FIG. 4. When the transmission signal is a 28 Gbps signal, and the clock frequency is 14 GHz, tr=0.35/(14×10⁹)=25 ps. In this case, the charge amount Q necessary for the transmission signal to rise is given by the equation of Q=i×tr=125×10⁻¹⁵ C. Accordingly, the capacitance C is given by the equation of C=(0.125×10⁻¹⁵)/Vdd=0.125 pF.

In the practical state, as the actual waveforms shown in (b) of FIG. 4 travel on the signal lines 2a, the rising period tr increases, and after a half of the clock period elapses, the amplitude of the current rapidly decreases and becomes unusable. Hence, it is common to pre-emphasize the waveforms as shown in FIG. 5 by a circuit within a chip to, suppress the rising period tr from increasing. The practical waveforms are shown in (a) of FIG. 5. The pre-emphasis waveforms are shown in (b) of FIG. 5.

A small open stub provided in a transmission line immediately after a driver causes a signal waveform to delay in rise timing by the time necessary to charge the small open stub. That is, this small open stub serves as a small capacitor. Generally, a capacitive entrance impedance, which is used to show a frequency characteristic of a chip capacitor, is smaller than the characteristic impedance (100Ω in this embodiment) of the transmission line. Accordingly, since the chip capacitor is charged before electric charge flows to the transmission line, the rise timing is delayed. The structure of the present invention has been made utilizing this known principle skillfully.

The impedance of such a chip capacitor rapidly increases when the frequency of a transmission signal increases above 2 GHz due to the parasitic inductance. In this embodiment where the assumed frequency of the transmission signal is 14 GHz, the impedance is from 1 kΩ to 100 kΩ, which is much larger than the characteristic impedance of 100Ω of the signal lines. Accordingly, it is unreasonable to use such a chip capacitor in this range of the transmission signal. The open stubs 7 are charged by the characteristic impedance while the signal waveform of a signal passes therethrough, and accordingly have no frequency-dependent characteristic. Therefore, the open stubs 7 have a capacitance which is substantially the same as a capacitance component corresponding to the frequency range from the sine wave component DC of the signal to the harmonic of 14 GHz×9.

At the moment when the signal outputted from the driver stops rising after the open stubs 7 are fully charged, a current starts to flow from the open stubs 7 causing an overshoot above ½Vdd. This state is expected to provide some positive effect even when the amount of the electric charge charged in the open stubs 7 is significantly smaller than that charged at the rise start timing. It was found through simulation that some positive effect can be obtained if the amount of electric charges charged in the open stubs 7 is in the range of ⅓ to 1/10 of that charged at the rise start timing.

Next, the structure of such a capacitance component is explained in detail. Basically, the capacitance component is formed by forming the structure shown in FIG. 1 in which two open stubs 7 having the same diameter as the width of the signal lines of the differential transmission line 2 are opposed to each other along the depth direction of the multilayer wiring board 1. The distal ends of these open stubs 7 are open. To increase the capacitance, a multiple structure may be employed to reduce the entrance impedance of the open stubs 7. Further, via pads may be provided if the amount of electric charges charged in the open stubs 7 is in the range of ⅓ to 1/10 of that charged at the rise start timing.

First, there is calculated the entrance impedance of the open stubs 7, which is the same as the transmission line characteristic impedance Z0 given by the following approximation. In the following approximation, d is the distance between the centers of the open stubs 7, r is the radius of the open stubs 7, and εereff is the effective permittivity of the open stubs 7. Here it is assumed that d=160 μm, r=50 μm, and effective permittivity=3.

$${Z}_{0} = \frac{377}{2 π \sqrt{{ɛ}_{reff}}} {cosh}^{- 1} ( \frac{2 {d}^{2} - {( 2 r )}^{2}}{{( 2 r )}^{2 }} ) = 34.65 \times 2.91 = 100.8 Ω$$

In this assumption, Z0 is approximately 100Ω. When the signal rises, electric charge flows to the open stubs 7 at the ratio of 100Ω/(100Ω+100Ω)=0.50. When a multiple structure, for example, a quadruplex structure is employed, since the ratio increases to 100Ω/(250Ω+100Ω)=0.80, most of the electric charge flows into the open stubs 7 first. During this time, the rise timing is delayed and the overshoot as shown in (b) of FIG. 5 occurs.

The characteristic impedance of the differential transmission line 2 depends on the thickness (width) of the signal lines 2a and the distance between the signal lines 2a. Accordingly, the thickness of the signal lines 2a has to be large to some extent so that the direct current resistance of the signal lines 2a is not excessively large. However, since the distance between the signal lines 2a has to be increased to increase the thickness of the signal lines 2a, an optimum design is required for the limited surface area.

For the case of high-density mounting, it is important to increase the wiring density of the multilayer wiring board 1 by reducing the pitch between the adjacent signal line pair with less crosstalk. The first condition required of the open stubs 7 is that the characteristic entrance impedance is smaller than 33Ω so that the signal energy flows to the open stubs 7 at the ratio of more than 100Ω/(33Ω+100Ω)=0.75. The second condition required of the open stubs 7 is that the mounting area thereof is sufficiently small. Accordingly, it is most preferable that the diameter of the open stubs 7 is equivalent to the width of the signal lines 2a.

As described above, according to this embodiment, the open stubs 7 are provided in the signal lines 2a of the differential transmission line 2, the width of the open stub 7 being the same of the width of the signal line 2a. This provides the advantage that the signal attenuation characteristic can be improved by a simple structure. Since the width of the open stubs 7 is the same as the width of the signal lines 2a so that a sufficiently large amount of charge energy flows into the open stubs 7, it is possible to prevent the mounting area of the open stubs 7 from becoming excessively large.

It is preferable that the open stubs 7 are disposed as closely as possible to the signal transmission end of the differential transmission line 2 for the purpose of forming the pre-emphasis waveforms. It is most preferable that the open stubs 7 are disposed immediately below the lands 7 on which that electronic component 11 is mounted. However, when it is difficult to dispose the open stubs 7 immediately below the lands 7, they should be disposed at a position as close as possible to the lands 6. The inventors of the present invention found through study that the above purpose can be achieved when the open stubs 7 are disposed within 1% of the entire distance of the differential transmission line 2 from the lands 6.

It is preferable that the open stubs 7 have a sufficient length to obtain the necessary capacitance. When it is difficult for the open stubs 7 to have a sufficient length, a plurality of the open stubs 7 may be provided to each signal line 2a, so that the necessary capacitance for forming the pre-emphasis waveforms can be obtained without increasing the length in the depth direction of the open stubs 7. It is also preferable that the open stub 7 of one of the paired signal lines 2a and the corresponding open stub 7 of the other signal line 2a are disposed so as to be opposite to each other with respect to the direction in which the paired signal lines 2a extend.

### Second to Fourth Embodiments

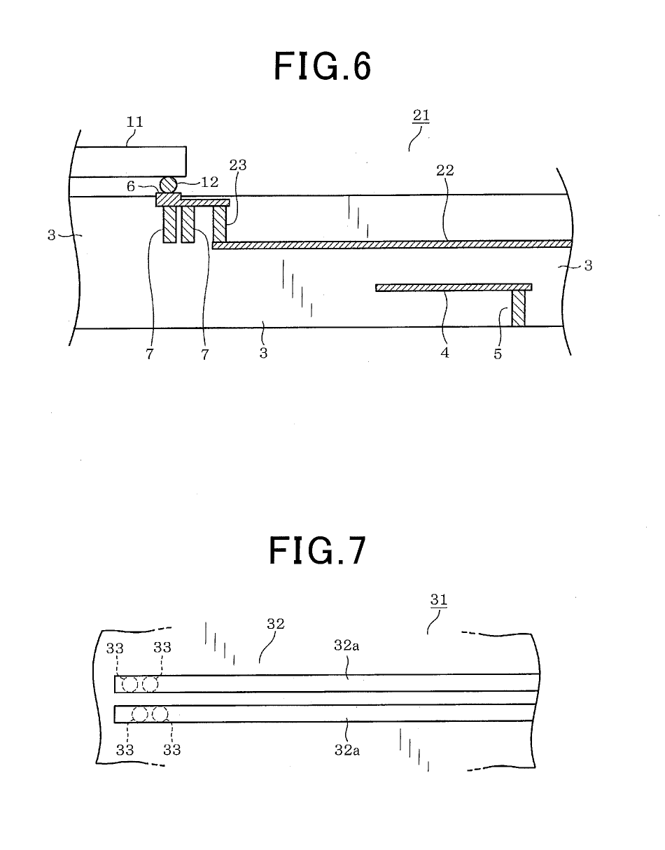

FIG. 6 schematically shows the structure of a multilayer wiring board 21 according to a second embodiment of the invention. The second embodiment differs from the first embodiment in that a differential transmission line 22 is formed within the insulating layer 3. In this embodiment, the differential transmission line 22 extends from the lands 6 along the surface of the multilayer wiring board 21 to the right in FIG. 6 to reach an interlayer connecting section 23, and extends from the interlayer connecting sections 23 to the right within the insulating layer 3. Like in the first embodiment, in this embodiment, the open stubs 7 are provided in the signal transmission end of the differential transmission line 22. The second embodiment provides the same advantages as those provided by the first embodiment.

FIG. 7 schematically shows the structure of a multilayer wiring board 31 according to a third embodiment of the invention. The third embodiment differs from the first embodiment in the location of open stubs 33 on a differential transmission line 32. In this embodiment, the differential transmission line 32 is constituted of a pair of signal lines 32a, and two open stubs 33 are provided in the signal transmission end of each of the pair of the signal lines 32a. Each open stub 33 of one of the paired signal lines 32a is disposed at a position which is shifted from a position of the corresponding open stub 33 of the other signal line 31 in the direction in which these signal lines 32a extend. The third embodiment provides the same advantages as those provided by the first embodiment.

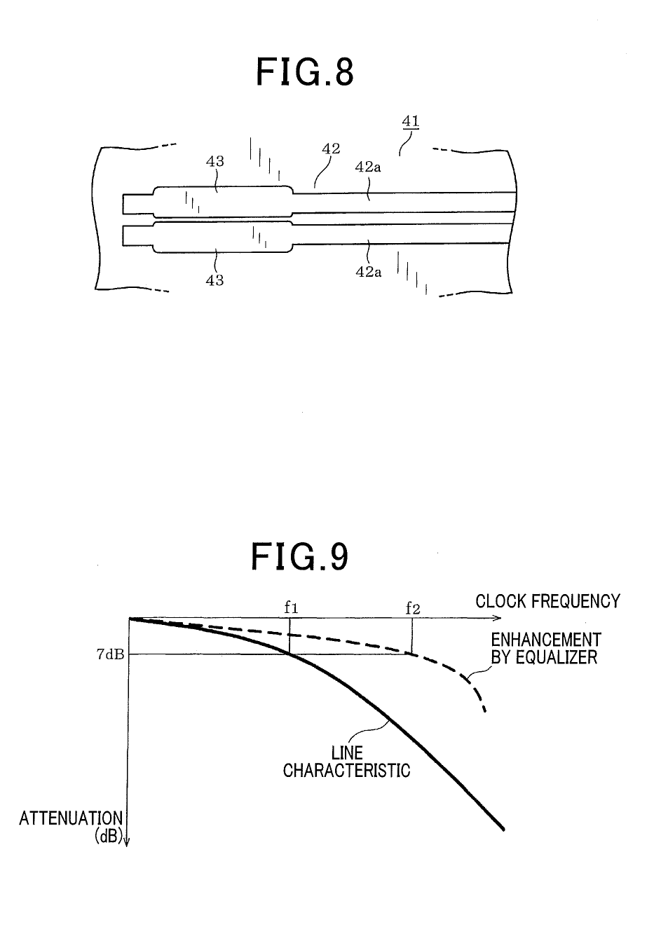

FIG. 8 schematically shows the structure of a multilayer wiring board 41 according to a fourth embodiment of the invention. The fourth embodiment differs from the first embodiment in the following points. In this multilayer wiring board 41, a pair of signal lines 42a of a differential transmission line 42 extend along the surface of the insulating layer 3, and a stub 43 is provided in each of the signal lines 42a so as to spread in the width direction of the signal lines 42a. These stubs 43 are formed integrally with the signal lines 42a at the time of forming the surface conductor pattern of copper foil on the insulating layer 3 (substrate).

The inventors of the present invention confirmed through study that the same advantageous effect can be obtained by providing the stub 43 in each of the signal lines 42a so as to spread in the width direction of the signal lines 42a instead of providing the open stubs 7 so as to extend from the signal lines 42a in the thickness direction of the insulating layer 3.

In the above described first to third embodiments, each of the signal lines is provided with two open stubs. However, each of the signal lines may be provided with only one open stub if the desired effect can be obtained. The inventors of the present invention found through study that the number of the open stubs is preferably smaller than or equal to four.

The above explained preferred embodiments are exemplary of the invention of the present application which is described solely by the claims appended below. It should be understood that modifications of the preferred embodiments may be made as would occur to one of skill in the art.

What is claimed is:

1. A multilayer wiring board comprising:
insulating layers stacked on one another;
lands formed on an upper surface part of the multilayer wiring board, an electronic component being mounted on the lands; and
a differential transmission line formed on or in each of the insulating layers, the differential transmission line being constituted of a pair of signal lines which extend from the lands toward a signal receiving end, wherein
each of the signal lines is provided with an open stub which extends in a stacking direction of the insulating layers and has a same width as a width of the signal lines, one end of the open stub being connected to a corresponding one of the signal lines, and another end of the open stub being open.

2. The multilayer wiring board according to claim 1, wherein the open stubs are disposed within a distance smaller than 1% of an entire length of the differential transmission line from the lands that serve as a signal transmitting end.

3. The multilayer wiring board according to claim 2, wherein the open stubs are disposed immediately below the lands that serve as the signal transmitting end.

4. The multilayer wiring board according to claim 1, wherein a plurality of the open stubs are provided to each of the signal lines so as to be arranged in a direction in which the signal lines extend.

5. The multilayer wiring board according to claim 1, wherein the open stub of one of the signal lines and the open stub of another signal line are disposed at positions opposite to each other with respect to a direction in which the signal lines extend.

6. The multilayer wiring board according to claim 1, wherein the open stub of one of the signal lines and the open stub of another signal line are disposed at positions shifted from each other in a direction in which the signal lines extend.

7. A multilayer wiring board comprising:
insulating layers stacked on one another;
lands formed on an upper surface part of the multilayer wiring board, an electronic component being mounted on the lands; and
a differential transmission line formed on or in each of the insulating layer except the uppermost insulating layer, the differential transmission line being constituted of a pair of signal lines which extend from the lands toward a signal receiving end, wherein
each of the signal lines is provided with a stub which extends along a surface of the insulating layer and spreads in a width direction of the signal line.
